(19) United States
(12) Patent Application Publication
(10) Pub. No.: US 2006/0223208 A1
(43) Pub. Date: Oct. 5, 2006

(54) Optical device

(75) Inventors: Nalinkumar L Patel, Cambridge (GB); Mark Leadbeater, Cambridge (GB); Craig Murphy, Cambridge (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Cambridge Display Technology Limited, Cambridge (GB)

(21) Appl. No.: 10/531,070

(22) PCT Filed: Oct. 10, 2003
(86) PCT No.: PCT/GB03/04406

§ 371 Date: Feb. 21, 2006

(30) Foreign Application Priority Data
Oct. 10, 2002 (GB) 0223510.9

(51) Int. Cl. H01L 21/00

(52) U.S. Cl. 438/29; 438/69; 438/82

(57) ABSTRACT

The disclosure relates to a method of forming an optical device including the steps of (i) providing a substrate carrying a first electrode capable of injecting or accepting charge carriers of a first type; (ii) depositing a polyfluorene over the first electrode; and (iii) forming over the polyfluorene a second electrode capable of injecting or accepting charge carriers of a second type, wherein the polyfluorene is heated before and after forming the second electrode. The disclosure has particular application in the preparation of organic light emitting devices.

### FIELD OF THE INVENTION

This invention relates to organic optical devices comprising a layer of heat treated organic material and methods for the production thereof.

### BACKGROUND OF THE INVENTION

Electroactive organic materials are now frequently used in a number of optical devices such as in organic light emitting diodes (“OLEDs”) as disclosed in WO 90/13148 (wherein the active organic material is a polymer), U.S. Pat. No. 4,539,507 (wherein the active organic material is of the type known as “small molecule”), photovoltaic devices as disclosed in WO 96/16449 and photodetectors as disclosed in U.S. Pat. No. 5,523,555.

Formation of an OLED, or indeed the other aforementioned devices, Is by deposition, in sequence, of an anode, an organic electroluminescent layer and a cathode onto a substrate. In operation, holes are injected into the device through the anode and electrons are injected into the device through the cathode. The holes and electrons combine in the organic electroluminescent layer to form an exciton which then emits light by radiative decay.

Further moieties may be provided, e.g. to assist in transport of holes or electrons.

In a typical polymer light emitting device (“PLED”), the electroluminescent polymer is soluble in common organic solvents and the polymer is deposited by any one of a number of known solution deposition methods including spin-coating, inkjet printing as disclosed in EP 0880303, flexographic printing, screen printing and doctor blade coating.

In the case of a typical small molecule light emitting device, the electroluminescent material is deposited by evaporation.

Another method of deposition, applicable to small molecules and polymers, is laser transfer as described in EP 0851714.

Both polymer and small molecule OLEDs are commonly provided with further organic materials in addition to the electroluminescent material, in particular hole transporting and/or electron transporting materials. For example, WO 99/48160 discloses a blend of an electroluminescent polymer with one or both of an electron transporting polymer and a hole transporting polymer. Similarly, small molecule OLEDs commonly comprise three distinct layers, with a layer of electroluminescent material located between a hole transporting material and an electron transporting material.

The physical properties of a charge transporting or electroluminescent layer such as its morphology, or phase separation in the case of a blend, will depend in part on its deposition conditions. It has been postulated that modification these properties by heat treatment of the layer may in turn affect device performance. For example, polymer chains may relax and take on a new conformation at temperatures above the glass transition temperature (Tg) of that polymer.

There exists a sizeable body of work on the effect that heat treatment of the electroluminescent material of an OLED has on device performance. This includes the following:

J. Appl. Phys. 91(3), 2002, 1595-1600 discloses heat treatment of poly(2-methoxy-5-(2′-ethyl-hexyl (MEH-PPV) prior to deposition of the cathode (hereinafter referred to as pre-cathode heating). Annealing below Tg is reported to improve electroluminescent efficiency of a single layer device; annealing above Tg is reported to improve hole injection efficiency.

Synth. Met. 117 (2001) 249-251 discloses heat treatment of MEH-PPV above the Tg of the polymer either before or after deposition of the cathode. The most significant improvements are reported to be a fall in operating voltage and increase in quantum efficiency upon heat treatment following cathode deposition (hereinafter referred to as post-cathode heating).

Adv. Mater. 2000, 12(11), 801-804 discloses pre-cathode heating of MEH-PPV above or below Tg and/or post-cathode heating above Tg. The most efficient device is reported to be that undergoing post-cathode heating only. Similarly, Appl. Phys. Lett. 77(21), 2000, 3334-3336 discloses pre-cathode heating below Tg and post-cathode heating above Tg, however the pre-cathode heating in this case is taught to be only for the purpose of removing residual solvent.

Appl. Phys. Lett. 80(3), 2002, 392-394 discloses post-cathode heating of a polythiophene derivative above or below Tg. Device performance improvements are reported at temperatures above and below Tg.

Appl. Phys. Left. 81(4), 2002, 634-636 discloses post-cathode heating of a copolyfluorene. Improved device performance is reported at temperatures below Tg.

JP 2000-311784 discloses heat treatment of a small molecule below Tg either after or at the time of small molecule film formation.

Improvements in the efficiency of photovoltaic devices by heat treatment are disclosed in J. Appl. Phys. 88(12), 2000, 7120-7123 and in Solar Energy Materials and Solar Cells, 61, 2000, 53-61.

The aforementioned art discloses various heat treatments either before or after cathode deposition and at temperatures above or below Tg. These disclosures teach improvements in device performance such as quantum efficiency, turn on voltage and brightness. However, perhaps the most signficant shortcoming of current OLED displays is the relatively short lifetime of blue emissive materials known to date (by “lifetime” is meant the time taken for the brightness of the device to decay to half its original brightness at a fixed current). Significant effort has been devoted to improvement of blue lifetime by development of novel blue electroluminescent materials, device architectures and processes.

It is therefore a purpose of the invention to improve the lifetime of organic semiconducting materials, in particular blue electroluminescent materials.

### SUMMARY OF THE INVENTION

a first aspect, the invention provides a method of forming an optical device comprising the steps of:
providing a substrate carrying a first electrode capable of injecting or accepting charge carriers of a first type;
depositing a polyfluorene over the first electrode; and
forming over the polyfluorene a second electrode capable of injecting or accepting charge carriers of a second type

wherein the polyfluorene is heated before and after forming the second electrode.

By “polyfluorene” is meant a polymer comprising optionally substituted or fused fluorene repeat units.

Preferably, the polyfluorene comprise optionally substituted units of formula (I):

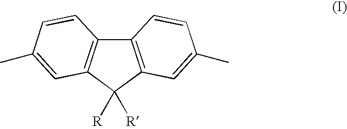

wherein R and R′ are independently selected from hydrogen or optionally substituted alkyl, alkoxy, aryl, arylalkyl, heteroaryl and heteroarylalkyl, and R and R′ may be combined to form an optionally substituted monocyclic or polycyclic group.

Preferably, at least one of R and R′ comprises an optionally substituted phenyl or C₄-C₂₀ alkyl group.

Preferably, at least one of the heat treatment steps is at or below the glass transition temperature of the polyfluorene.

Preferably, both of the heat treatment steps are at or below the glass transition temperature of the polyfluorene.

Preferably, the optical device is an electroluminescent device.

Preferably, the first electrode is an anode and the second electrode is a cathode. Preferably, the cathode comprises a metal having a workfunction of less than 3.5 eV. More preferably, the cathode comprises a layer of calcium.

Preferably, a layer of dielectric material is located between the polyfluorene and the cathode. Preferably, the layer of dielectric material comprises a metal fluoride.

A method according to any preceding claim wherein a layer of conductive organic material is provided between the first electrode and the first layer. Preferably, the layer of conductive organic material is PEDT/PSS.

Preferably, the polyfluorene comprises a plurality of regions including at least two of a hole transporting region, an electron transporting region and an emissive region.

Preferably, the polyfluorene comprises a hole transporting region, an electron transporting region and an emissive region.

Preferably, the polyfluorene is a blue electroluminescent material.

In a second aspect, the invention provides an optical device obtainable by the method according to the first aspect of the Invention. Preferably, the optical device is an electroluminescent device.

In a third aspect, the invention provides a method of forming an optical device comprising the steps of:
providing a substrate carrying a first electrode capable of injecting or accepting charge carriers of a first type;
depositing an organic semiconductor over the first electrode; and
forming over the organic semiconductor a second electrode capable of injecting or accepting charge carriers of a second type

wherein the organic semiconductor is heated below its glass transition temperature before and after forming the second electrode.

In a fourth aspect, the invention provides an optical device obtainable by the method according to the third aspect of the invention. Preferably, the optical device is an electroluminescent device.

By “blue electroluminescent material” is meant an organic material that by electroluminescence emits radiation having a wavelength in the range of 400-500 nm, more preferably 430-500 nm.

The inventors have surprisingly found that the lifetime of a polyfluorene, in particular a blue electroluminescent polyfluorene, may be improved by a combination of pre- and post-cathode heat treatment. This combination has been found to lead to a greater increase in lifetime than only one of either pre- or post-cathode heat treatment.

It has been found that the temperature of the heat treatment, in particular heat treatment above or below Tg, has little or no effect on lifetime. However, higher efficiency is maintained at temperatures around or below the Tg of the electroluminescent material.

### BRIEF DESCRIPTION OF THE DRAWINGS

The present invention will now be described in further detail, by way of example only, with reference to the accompanying drawings in which:

FIG. 1 shows a PLED or photovoltaic device prepared according to the method of the invention

FIG. 2 shows a graph of luminance vs. time of a PLED according to the invention relative to devices not heated or subjected to only one of pre- or post-cathode heating.

### DETAILED DESCRIPTION OF THE INVENTION

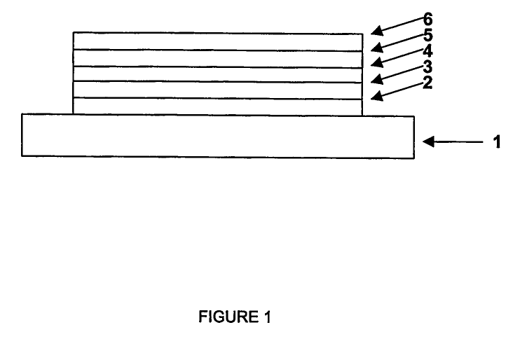

With reference to FIG. 1, a PLED or photovoltaic device prepared according to the method of the invention comprises a substrate 1, an anode 2 of indium tin oxide, a layer 3 of organic hole transport material, a layer 4 of organic semiconducting material or materials, an electron transporting layer 5 and a cathode 6.

Optical devices tend to be sensitive to moisture and oxygen. Accordingly, the substrate 1 preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

Although not essential, the presence of layer 3 of organic hole injection material is desirable as it assists hole injection from the anode into the layer or layers of semiconducting polymer. Examples of organic hole injection materials include PEDT/PSS as disclosed in EP 0901176 and EP 0947123, or polyaniline as disclosed in U.S. Pat. No. 5,723,873 and U.S. Pat. No. 5,798,170.

Cathode 6 is selected in order that electrons are efficiently injected into the device and as such may comprise a single conductive material such as a layer of aluminium. Alternatively, it may comprise a plurality of metals, for example a bilayer of calcium and aluminium as disclosed in WO 98/10621. A thin layer of dielectric material 5 such as lithium fluoride may be provided to assist electron injection as disclosed in, for example, WO 00/48258.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142.

In a practical device, at least one of the electrodes is semi-transparent in order that light may be absorbed (in the case of a photoresponsive device) or emitted (in the case of an OLED). Where the anode 1 is transparent, it typically comprises indium tin oxide. Examples of transparent cathodes are disclosed in, for example, GB 2348316.

The organic semiconducting material or materials comprising layer 4 may be polymers or small molecules. Examples of suitable semiconducting polymers are disclosed in Adv. Mater. 2000 12(23) 1737-1750 and references therein. A single polymer or a polymer blend may be deposited from solution to form layer 4. Where a plurality of polymers are deposited, they preferably comprise a blend of at least two of a hole transporting polymer, an electron transporting polymer and, where the device is a PLED, an emissive polymer as disclosed in WO 99/48160. Alternatively, layer 5 may be formed from a single second semiconducting polymer that comprises regions selected from two or more of hole transporting regions, electron transporting regions and emissive regions as disclosed in, for example, WO 00/55927 and U.S. Pat. No. 6,353,083. Each of the functions of hole transport, electron transport and emission may be provided by separate polymers or separate regions of a single polymer. Alternatively, more than one function may be performed by a single region or polymer. In particular, a single polymer or region may be capable of both charge transport and emission. Each region may comprise a single repeat unit, e.g. a triarylamine repeat unit may be a hole transporting region. Alternatively, each region may be a chain of repeat units, such as a chain of polyfluorene units as an electron transporting region. The different regions within such a polymer may be provided along the polymer backbone, as per U.S. Pat. No. 6,353,083, or as groups pendant from the polymer backbone as per WO 01/62869.

In addition to layer 4, the optical device may optionally comprise further layers of organic semiconducting material. In particular, a plurality of layers of organic semiconducting materials may be provided as an alternative to a blend of those materials.

The organic semiconductor of layer 4 is preferably a polyfluorene. Examples of suitable fluorene repeat units for a polyfluorene include 2,7-linked 9,9 dialkyl fluorenes, 2,7-linked 9,9 diaryl fluorenes, 2,7-linked 9,9 spirofluorenes (as disclosed in EP 0707020) and indenofluorenes (as disclosed in Adv. Mater. (2001), 13(14), 1096-1099).

The heat treatment of the optical device is preferably at temperatures up to and including the Tg of the organic semiconducting material. Practically, the lowest temperature for the heat treatment is around 60-70° C. The heat treatment may last from around 2 minutes up to 12 hours, preferably around 10 minutes up to 1 hour. The length of time of the heat treatment depends in part on the temperature—e.g. where heat treatment is at or around the Tg of the organic semiconducting material, the time for the heat treatment is reduced accordingly. In addition, the efficiency of heat transfer from the heat source (e.g. a hotplate or an oven) to the optical device should be taken into account in determining this length of time. Heat treatment should take place in an inert environment, such as a nitrogen atmosphere, due to the susceptibility of organic semiconducting materials, and many cathodes, to degradation in air.

The optical device prepared according to the method of the invention is preferably a PLED when the first and second electrodes inject charge carriers. In this case, layer 4 is a light emitting layer.

The optical device is preferably a photovoltaic device or photodetector when the first and second electrodes accept charge carriers. In this case, the second layer preferably comprises a polymer or polymers capable of hole and electron transport.

### EXAMPLE 1

A blue electroluminescent polymer was prepared in accordance with the process of WO 00/53656 by reaction of 9,9-di-n-octylfluorene-2,7-di (ethylenylboronate) (0.5 equivalents), 2,7-dibromo-9,9(0.3 equivalents), N,N-di(4-bromophenyl)-sec-butylphenylamine (0.1 equivalents) and N,N′-di(4-bromophenyIN,N′-di(4-n-butylphenyl)-1,4-diaminobenzene (0.1 equivalents) to give polymer P1:

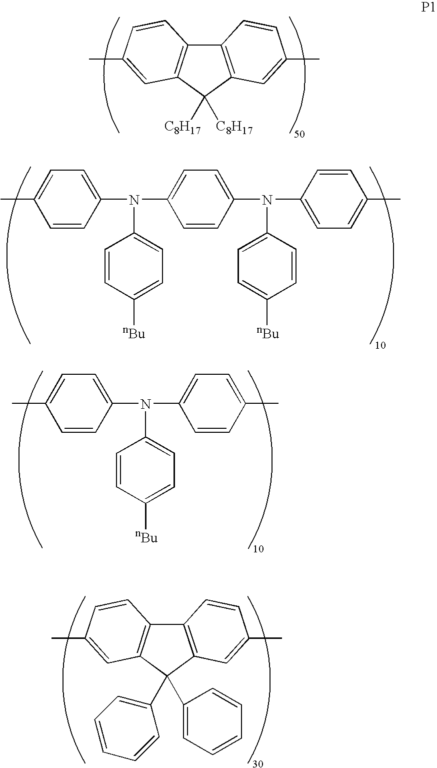

Polymer P1 has a Tg of 140° C.

Onto a substrate of glass carrying an anode of indium tin oxide (available from Applied Films of Colorado, USA) was deposited a solution of PEDT/PSS (available from H C Starck of Leverkusen, Germany as Baytron P) by spin coating. The PEDT/PSS film was then heated to remove solvent.

Onto the PEDT/PSS was deposited by spin-coating a film of polymer P1. The polymer was heated by placing the substrate on a hotplate at 90° C. for 1 hour in an inert atmosphere.

Onto the film of polymer P1 was deposited by evaporation a layer of lithium fluoride followed by a cathode comprising a first layer of calcium and a second layer of aluminium as described in WO 00/48258.

Following cathode deposition, the polymer was heated by placing the substrate on a hotplate at 90° C. for 1 hour in an inert atmosphere.

The device was encapsulated using an airtight metal container available from SAES Getters SpA of Milan, Italy.

### Comparative Example 1

A device was prepared in accordance with example 1 except that the device was not heated.

### Comparative Example 2

A device was prepared in accordance with example 1 except that the device was only subjected to pre-cathode heating.

### Comparative Example 3

A device was prepared in accordance with example 1 except that the device was only subjected to post-cathode heating.

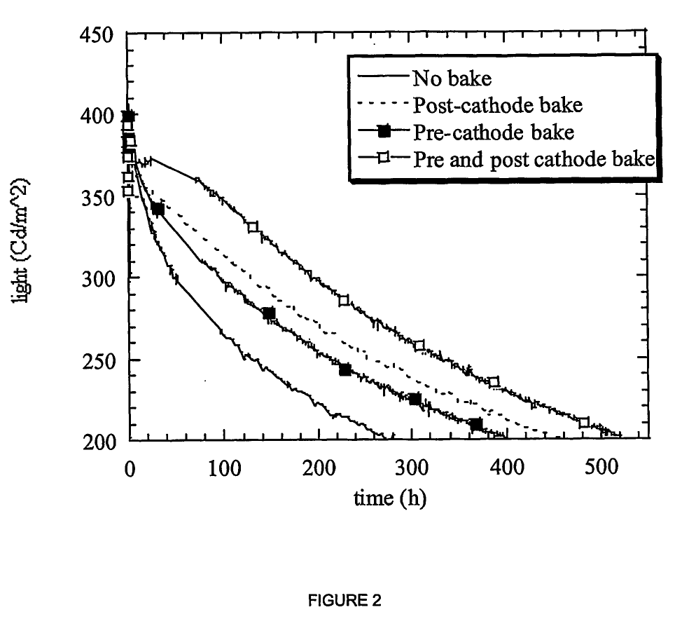

As can be seen from FIG. 2, the lifetime of the device according to the invention was improved relative to any of the devices treated in accordance with the comparative examples.

Lifetime of devices heat treated (a) below and (b) in excess of Tg of P1 was not found to be significantly different, however the efficiency of the device heated in excess of Tg of P1 was found to be significantly lower. There does not appear to be a significant correlation between lifetime and efficiency of devices prepared by the method of the invention.

Although the present invention has been described in terms of specific exemplary embodiments, it will be appreciated that various modifications, alterations and/or combinations of features disclosed herein will be apparent to those skilled in the art without departing from the spirit and scope of the invention as set forth in the following claims.

1. A method of forming an optical device comprising the steps of:
providing a substrate carrying a first electrode capable of infecting or accepting charge carriers of a first type;
depositing a polyfluorene over the first electrode; and
forming over the polyfluorene a second electrode capable of injecting or accepting charge carriers of a second type,
and further comprising heating the polyfluorene before and after forming the second electrode.

2. A method according to claim 1 wherein the polyfluorene comprises optionally substituted units of formula (I); 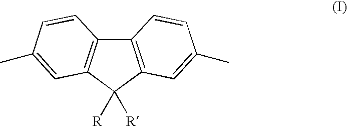
wherein R end R′ are independently selected from hydrogen or optionally substituted alkyl, alkoxy, aryl, arylalkyl, heteroaryl and heteroarylalkyl, and R and R′ may be combined to form an optionally substituted monocyclic or polycyclic group.

3. A method according to claim 1 wherein at least one of R and R′ comprises an optionally substituted phenyl or C₄-C₂₀ alkyl group.

4. A method according to claim 1 wherein at least one of the heat treatment steps is at or below the glass transition temperature of the polyfluorens.

5. A method according to claim 4 wherein both of the heat treatment steps are at or below the glass transition temperature of the polyfluorene.

6. A method according to claim 1 wherein the optical device is an electroluminescent device.

7. A method according to claim 6 wherein the first electrode is an anode and the second electrode is a cathode.

8. A method according to claim 7 wherein the cathode comprises a metal having a workfunction of less than 3.5 eV.

9. A method according to claim 8 wherein the cathode comprises a layer of calcium.

10. A method according to claim 7 further comprising locating a layer of dielectric material between the polyfluorene and the cathode.

11. A method according to claim 10 wherein the layer of dielectric material comprises a metal fluoride.

12. A method according to claim 1 comprising providing a layer of conductive organic material between the first electrode and the first layer.

13. A method according to claim 12 wherein the layer of conductive organic material is PEDT/PSS.

14. A method according to claim 1 wherein the polyfluorene comprises a plurality of regions including at least two of a hole transporting region, an electron transporting region and an emissive region.

15. A method according to claim 14 wherein polyfluorene comprises a hole transporting region, an electron transporting region and an emissive region.

16. A method according to claim 1 wherein the polyfluorene is a blue electroluminescent material.

17. An optical device obtained by the method according to claim 1.

18. An optical device according to claim 17 that is an electroluminescent device.

19. A method of forming an optical device comprising the steps of:
providing a substrate carrying a first electrode capable of injecting or accepting charge carriers of a first type;
depositing an organic semiconductor over the first electrode; and
forming over the organic semiconducting materiel a second electrode capable of injecting or accepting charge carriers of a second type, and further comprising heating the organic semiconductor below its glass transition temperature before end after forming the second electrode.

20. A method according to claim 19 wherein the organic semiconductor is a polymer.

21. A method according to claim 20 wherein the organic semiconductor is a polyfluorene.

22. A method according to claim 19 wherein the optical device is an electroluminescent device.

23. An optical device obtained by the method according to claim 20.

24. An optical device according to claim 23 that is an electroluminescent device.
